(19) United States
(12) Patent Application Publication
(10) Pub. No.: US 2002/0145431 A1
(43) Pub. Date: Oct. 10, 2002

(54) Positionable electrostatic discharge plate holder assembly

(76) Inventor: Glenn M. Brady, Cream Ridge, NJ (US)

Correspondence Address: DAVID L. DAVIS, ESQ., 203 MAIN STREET, METUCHEN, NJ, 08840, US

(21) Appl. No.: 09/829,108

(22) Filed: Apr. 9, 2001

(51) Int. Cl. G01R 29/12

(52) U.S. Cl. 324/457

(57) ABSTRACT

A positionable holder assembly for an electrostatic discharge plate includes a commercially available photographic-type tripod having a geared lateral arm. A non-conductive plate holder is attached to the lateral arm through a non-conductive intermediate support member so that no conductive material is horizontally closer to the plate than the electronic equipment being tested.

### BACKGROUND OF THE INVENTION

This invention relates to the testing of electronic equipment for electrostatic discharge susceptibility and, more particularly, to a positionable holder assembly for an electrostatic discharge plate used in such testing.

Certain electronic equipment must be tested for its susceptibility to electrostatic discharge. This is accomplished by holding a conductive plate (typically of copper) in a vertical plane next to the equipment being tested. It is necessary to be able to accurately position the plate relative to the electronic equipment vertically and horizontally. At the same time, care must be taken to insure that no conductive material is horizontally closer to the plate than the electronic equipment. Existing apparatus used to secure and accurately position the plate with respect to the electronic equipment under test has been found to be inadequate. Precise positioning of the plate is difficult with such apparatus, and the relatively heavy plate is not securely held. It would therefore be desirable to have an improved positionable holder assembly which satisfies the requirements of securely holding the plate and being able to accurately position it relative to the electronic equipment under test.

### SUMMARY OF THE INVENTION

According to the present invention, there is provided a positionable holder assembly for an electrostatic discharge plate, wherein the plate comprises a substantially rectangular planar conductive sheet. The holder comprises a non-conductive elongated holder member having a groove at a first end adapted to receive a first edge of the sheet. A non-conductive clamp member is provided at a second end of the holder member, the clamp member being adapted to clamp an opposed second edge of the sheet to the holder member. A support member is adapted for controllable movement along a defined line and an intermediate support member is adapted to secure the elongated member to the support member so that the sheet is held in a plane orthogonal to the defined line.

In accordance with an aspect of this invention, the intermediate support member includes a non-conductive U-shaped member having a base and a pair of arms. The distal ends of the pair of arms remote from the base are non-conductively secured to the holder member, and the base is secured to the support member.

### BRIEF DESCRIPTION OF THE DRAWINGS

The foregoing will be more readily apparent upon reading the following description in conjunction with the drawings in which like elements in different figures thereof are identified by the same reference numeral and wherein:

FIG. 1 illustrates the use of an electrostatic discharge plate in conjunction with a discharge gun and electronic equipment as practiced in the prior art;

FIG. 2 is a side view of a portion of the inventive holder assembly;

FIG. 3 is a front view of the portion shown in FIG. 2; and

FIG. 4 is a perspective view of the entire inventive holder assembly with the discharge plate in place.

### DETAILED DESCRIPTION

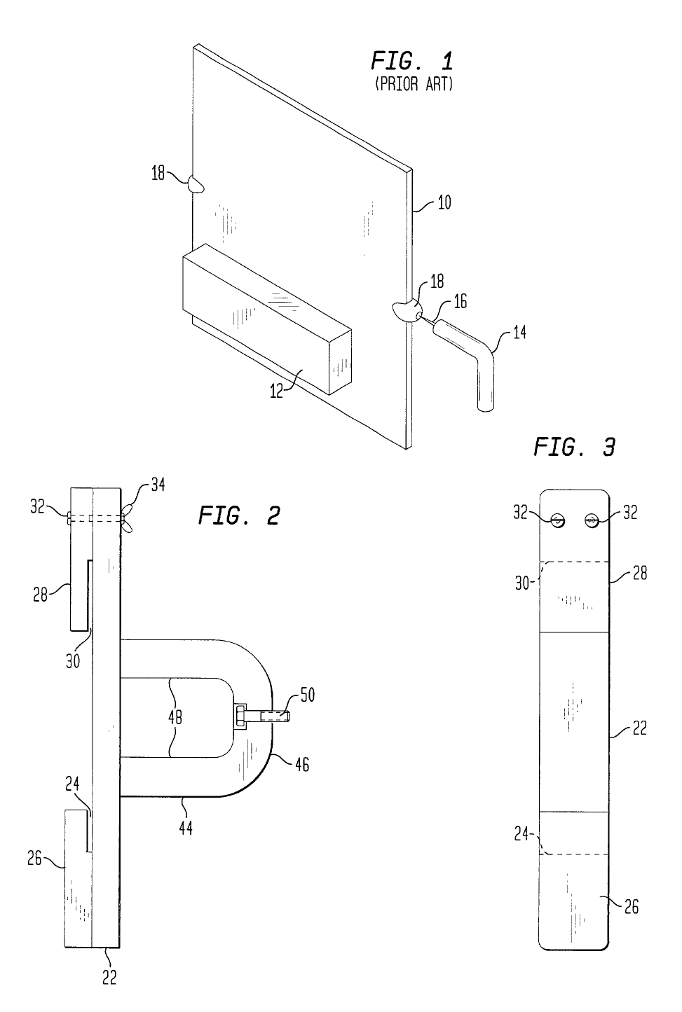

As shown in FIG. 1, an electrostatic discharge plate 10 is placed in close proximity to a piece of electronic equipment 12 being tested for electrostatic discharge susceptibility. The plate 10 is typically a copper sheet 0.5 meters square. An electrostatic discharge gun 14 is used to apply a high voltage to the plate 10, which diffuses the charge over a large area. The gun 14 has a needle tip 16 and the plate 10 is provided with receptacles 18 on opposed edges so that the needle tip 16 is more readily positioned.

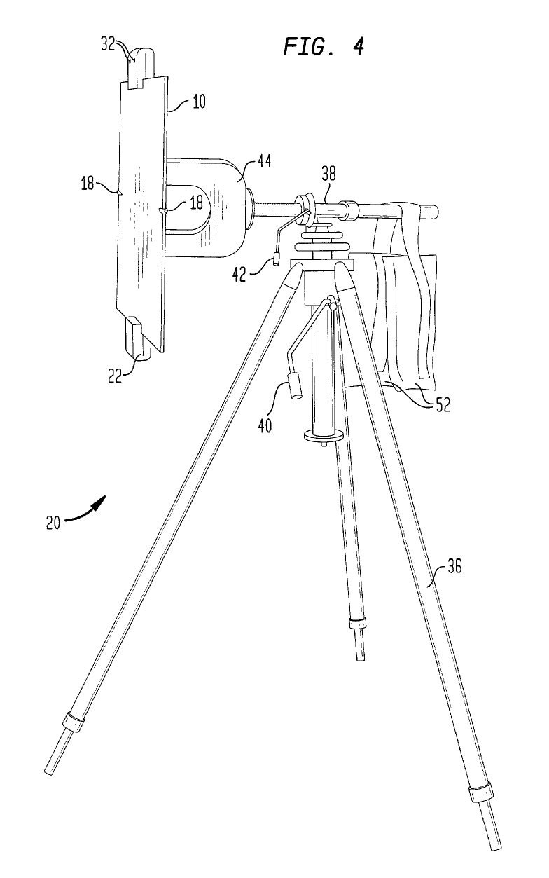

FIGS. 2-4 show an illustrative embodiment of a positionable holder assembly, designated generally by the reference numeral 20, and constructed in accordance with the principles of this invention, for holding and positioning the plate 10. The assembly 20 includes a non-conductive elongated holder member 22, illustratively made of wood. The holder member 22 is formed with a groove 24 at one end adapted to receive an edge of the plate 10, preferably with an interference fit. The groove 24 is formed by providing a notch in a block 26 which is secured to the holder member 22 in a nonconductive manner, as by adhesive and wooden dowels. At the other end of the holder member 22 there is provided a clamp member 28, also a non-conductive block having a notch to form a groove 30 for holding the plate 10 when the clamp member 28 is secured to the holder member 22 by a pair of bolts 32 and wing nuts 34.

The assembly 20 illustratively includes a commercially available photographic-type tripod 36 which has a geared lateral arm 38. As is conventional, the arm 38 can be precisely raised and lowered by means of the crank 40. Further, the arm 38 can be moved along a defined line by means of the crank 42, this defined line preferably being horizontal.

To secure the holder member 22 to the lateral arm 38 of the tripod 36, there is provided a non-conductive intermediate support member 44 which illustratively is a U-shaped wooden block. The block 44 has a base 46 and a pair of arms 48. The distal ends of the arms 48 are nonconductively secured to the holder member 22, illustratively by adhesive and wooden dowels. A bolt 50 extending through the base 46 is utilized to secure the intermediate support member 44 to the lateral arm 38 of the tripod 36. The aforedescribed arrangement insures that no conductive material is horizontally closer to the plate 10 than the electronic equipment being tested.

To insure stability, counterweights 52 may be hung from the lateral arm 38 remote from the intermediate support member 44.

Accordingly, there has been disclosed a positionable holder assembly for an electrostatic discharge plate used for testing the electrostatic discharge susceptibility of electronic equipment. While an illustrative embodiment of the present invention has been disclosed herein, it is understood that various adaptations and modifications to the disclosed embodiment are possible, and it is intended that this invention be limited only by the scope of the appended claims.

What is claimed is:

1. A positionable holder assembly for an electrostatic discharge plate, wherein the plate comprises a substantially rectangular planar conductive sheet, the assembly comprising:
a non-conductive elongated holder member having a groove at a first end adapted to receive a first edge of said sheet;
a non-conductive clamp member at a second end of said holder member adapted to clamp an opposed second edge of said sheet to said holder member;
a support member adapted for controllable movement along a defined line; and
an intermediate support member adapted to secure said holder member to said support member so that said sheet is held in a plane orthogonal to said defined line.

2. The assembly according to claim 1 wherein said intermediate support member includes a non-conductive U-shaped member having a base and a pair of arms, wherein the distal ends of the pair of arms remote from the base are non-conductively secured to the holder member and the base is secured to the support member.

3. The assembly according to claim 1 further comprising:
a counterweight attached to said support member remote from said intermediate support member.

4. The assembly according to claim 1 further comprising:
a photographic-type tripod;
wherein the support member is a geared lateral arm of the tripod.
